(19) United States
(12) Patent Application Publication
(10) Pub. No.: US 2009/0126986 A1
(43) Pub. Date: May 21, 2009

(54) Electromagnetic Shielding Film For Display Device, Filter Having The Same, And Method Of Fabricating The Same

(75) Inventors: Eui Soo Kim, ChungCheongNam-Do (KR); In Sung Sohn, ChungCheongNam-Do (KR)

Correspondence Address: LERNER, DAVID, LITTENBERG,;KRUMHOLZ & MENTLIK, 600 SOUTH AVENUE WEST, WESTFIELD, NJ, 07090, US

(73) Assignee: SAMSUNG CORNING PRECISION GLASS CO., LTD., Gyeongsangbuk-do (KR)

(21) Appl. No.: 12/273,679

(22) Filed: Nov. 19, 2008

(30) Foreign Application Priority Data
Nov. 20, 2007 (KR) 10-2007-0118503

(51) Int. Cl. H05K 9/00; B32B 3/10

(52) U.S. Cl. 174/389; 428/173; 428/167; 427/58

(57) ABSTRACT

An electromagnetic shielding film for a display device includes a transparent, resinous first base, an intaglio pattern formed on at least one side of the first base, and an electromagnetic shielding pattern containing a conductive material with which the intaglio pattern is filled. A method of fabricating an electromagnetic shielding film for a display device, includes the steps of coating a first curable resin on one surface of a transparent backing, forming an intaglio pattern on the first curable resin using a patterning roll and curing the first curable resin, filling the intaglio pattern with a second curable resin containing a conductive material, and curing the second curable resin.

### CROSS-REFERENCE TO RELATED APPLICATION

This application claims the benefit of Korean Patent Application No. 2007-0118503 filed on Nov. 20, 2007, in the Korean Intellectual Property Office, the disclosure of which is incorporated herein by reference.

### BACKGROUND OF THE INVENTION

1. Field of the Invention

The present invention relates to an electromagnetic shielding film for a display device, a filter having the same, and a method of fabricating the same, and more particularly, to an electromagnetic shielding film for a display device which can be fabricated by a simple process and can improve the capability to block electromagnetic waves, a filter having the same, and a method of fabricating the same.

2. Description of the Related Art

Display devices include televisions, monitors of personal computers, portable display devices, and so on. Display devices are recently getting larger sized and thinner.

Accordingly, flat panel display (FPD) devices such as plasma display panel (PDP) devices, liquid crystal display (LCD) devices, field emission display (FED) devices, and organic light emitting display (OLED) devices take the place of cathode ray tube (CRT) devices, which was representative of display devices.

Hereinafter, PDP devices and a filter therefor will be exemplified but the present invention is not limited thereto. For example, a filter according to the present invention can be used for large sized display devices such as OLED devices, LCD devices and FED devices; small sized display devices such as Personal Digital Assistance (PDA) devices, display devices for small sized game machines, display devices for small mobile phones; and flexible display devices.

Especially, PDP devices are in the limelight since they have excellent display characteristics such as high luminance, a high contrast ratio, low after-image, and a wide viewing angle.

PDP devices cause gas discharge between electrodes by applying a direct or alternating voltage to the electrodes, then a fluorescent material is irradiated with ultraviolet rays caused by the gas discharge to be activated, and thereby light is generated. PDP devices display images by using the generated light.

However, a conventional PDP device has drawbacks in that a large amount of electromagnetic waves and near infrared rays is emitted due to its intrinsic characteristics. The electromagnetic waves and near infrared rays emitted from the PDP device may have a harmful effect to the human body, and cause malfunction of precision appliances such as a cellular phone and a remote controller. Further, the PDP device has a high surface reflection and has lower color purity than CRT devices due to orange color light emitted from gas such as He or Xe.

Therefore, the PDP device uses a PDP filter in order to block the electromagnetic waves and near infrared rays, reduce the light reflection, and improve the color purity. The PDP filter is installed in front of a panel assembly. The PDP filter is generally fabricated by the adhesion or bonding between a plurality of functional layers such as an electromagnetic shielding layer, a near infrared ray blocking layer, a neon peak absorbing layer, etc.

The existing electromagnetic shielding layer is provided as a metal mesh film or a transparent conductive thin film. A metal mesh film can be fabricated by an etching method in which a copper film is bonded onto a polyethylene terephthalate (PET) film or the like, and then an unnecessary part of the copper film is removed through exposure and etching processes to obtain the mesh film. Further, another metal mesh film can be fabricated by a combination type method in which a seed layer for plating is printed by a printing process, and then the seed layer is plated with metal to a desired thickness. Further, recently, researches have been conducted into a direct print method of fabricating the electromagnetic shielding layer through the process of directly printing a conductive material onto a glass substrate.

A major problem of the etching method is that the process costs of the exposure and etching processes are expensive, and the material costs are also expensive since 90% or more of copper is removed by etching. Because of this problem, the combination type method of the printing and the plating was developed, but it also has a problem in that, since it is difficult to precisely print a wire as compared to the etching method, a wire width becomes thicker, which deteriorates visibility and increases the defective proportion. Thus, it is true that the combination type method is not frequently used compared to the etching method.

In the case of the direct print method, since it does not require the exposure and etching processes, it is a cost-effective method. However, the method also has a problem in that it is difficult to obtain a uniform wire width and to obtain a thin width of 10 to 20 μm but a thick thickness of 3 to 10 μm. Thus, the method is not frequently used too.

Further, the transparent conductive thin film has a problem in that the capability to block electromagnetic waves is poor compared to the metal mesh film.

### SUMMARY OF THE INVENTION

The present invention has been made to solve the foregoing problems with the prior art, and therefore an object of the present invention is to provide a filter for a display device which is equipped with an electromagnetic shielding film having a mesh pattern in which a wire depth is thicker while a wire width is thinner, thereby having a large ratio of depth to width.

Another object of the present invention is to provide a method of fabricating a filter for a display device which can lower the fabricating costs and the defective proportion, and provide an efficient fabricating process.

The objects the present invention intends to achieve are not limited to the above-mentioned objects, and other objects, which are not mentioned, will be apparently understood from below by those skilled in the art.

In one aspect of the invention, there is provided a filter for a display device including an electromagnetic shielding film having a first base, an intaglio mesh pattern formed on one side of the first base, an electromagnetic shielding pattern containing a conductive material with which the mesh pattern is filled.

In an embodiment of the invention, the intaglio pattern may be of a depth of 3 to 30 μm and a width of 5 to 30 μm, and a ratio of the depth to the width may be ranged between 0.3 and 3.

In an embodiment of the invention, the conductive material may be any one of (i) metal paste containing at least one metal of Co, Al, Zn, Zr, Pt, Au, Pd, Ti, Fe, Sn, In, Ni, Mo, W, Ag, and Cu, (ii) powders of at least one metal oxide of copper oxide, zinc oxide, indium oxide, tin oxide, indium tin oxide, aluminum zinc oxide, and indium zinc oxide, and (iii) at least one conductive polymer of polythiophene, polypyrrole, polyaniline, poly(3,4-ethylenedioxythiophene), poly(3-alkylthiophene), polyisothianaphthene, poly(p-phenylenevinylene), poly(p-phenylene), and derivatives thereof.

Further, the conductive material may be metal paste which is blackened by mixing carbon black or the like therein.

In an embodiment of the invention, the filter for a display device may further include an external-light blocking layer on the electromagnetic shielding film including a transparent second base on which a plurality of wedge grooves is formed and an external-light blocking pattern which contains a light absorbent material with which the wedge grooves are filled.

In an embodiment of the invention, the wedge grooves of the external-light blocking layer may be filled with a conductive material as well as the light absorbent material. The conductive material may be identical to or different from that contained in the electromagnetic shielding film.

In an embodiment of the invention, the filter for a display device may further include an electrode to be grounded, which is formed by printing conductive paste on at least one region of edges of the first base. The conductive paste may be silver paste.

In another aspect of the invention, there is provided a method of fabricating an electromagnetic shielding film for a display device, the method including the steps of coating a first curable resin on one surface of a transparent backing, forming an intaglio pattern on the curable resin using a pattern roll having an embossed mesh pattern, and curing the same, filling the intaglio pattern with a second curable resin containing a conductive material, and curing the second curable resin.

In an embodiment of the invention, the first curable resin may be ultraviolet-curable resin, and the second curable resin may be heat-curable resin.

According to the present invention, a filter for a display device includes the electromagnetic shielding film with the mesh pattern having a high ratio of depth to width, providing excellent capability to block electromagnetic waves.

In addition, the pattern of the electromagnetic shielding film is uniform and has thin width, which provides high visibility.

Furthermore, the present invention provides a method of fabricating a filter for a display device which can lower the fabricating costs and the defective proportion, and provide an efficient fabricating process.

### BRIEF DESCRIPTION OF THE DRAWINGS

The above and other objects, features and advantages of the present invention will be more clearly understood from the following detailed description provided in conjunction with the accompanying drawings, in which:

FIG. 1 is a cross-sectional view illustrating a PDP filter according to an embodiment of the present invention;

FIG. 2 is a perspective view illustrating an electromagnetic shielding film according to an embodiment of the present invention; and

FIG. 3 is a view illustrating a conceptive procedure of a method of fabricating a filter for a display device according to an embodiment of the present invention.

### DETAILED DESCRIPTION OF THE EXEMPLARY EMBODIMENT

The present invention will now be described more fully hereinafter with reference to the accompanying drawings, in which exemplary embodiments thereof are shown.

Although not illustrated in the figures, a PDP according to an embodiment of the present invention includes a case; a cover covering the case; a driving circuit board housed in the case; a panel assembly having light-emitting cells, in which a discharge phenomenon of gas occurs, and fluorescent layers; and a PDP filter. The light-emitting cell is filled with discharge gas. The discharge gas may be Ne—Xe based gas or He—Xe based gas, for example. The panel assembly basically emits light in a similar way to a fluorescent lamp in which ultraviolet rays are emitted from the discharge gas by electric discharge occurring in the light-emitting cell, and then excites the fluorescent layer to generate visible light.

The PDP filter is disposed in front of a front substrate of the panel assembly. The PDP filter may be disposed apart from or in contact with the front substrate of the panel assembly. The PDP filter can adhere to or bond with the front substrate of the panel assembly by an adhesive or a bonding agent, which prevents dust from sticking to the PDP filter and compensates for the strength of the filter.

The filter can include an electromagnetic shielding layer made of a high conductive material. The electromagnetic shielding layer is grounded through the cover to the case. Accordingly, before electromagnetic waves caused by the panel assembly reaches a viewer, it is discharged though the electromagnetic shielding layer and the cover to the case.

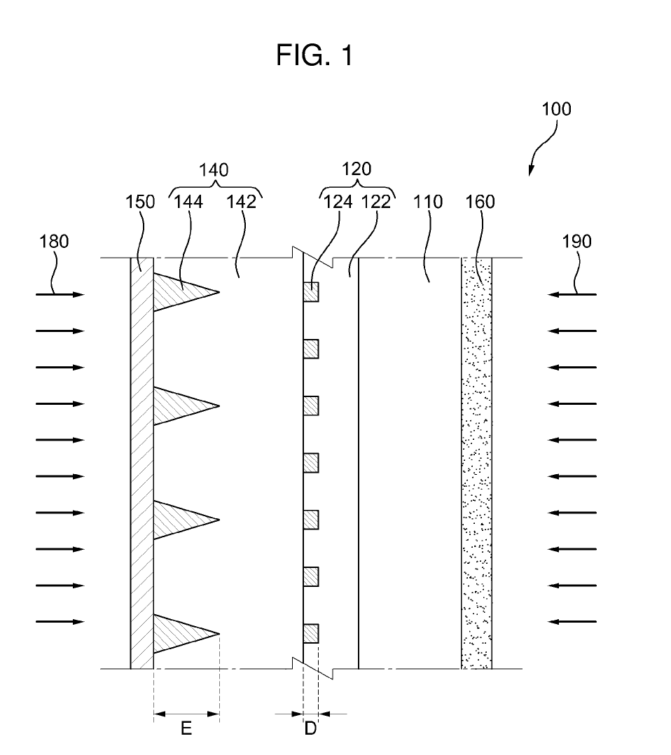

FIG. 1 is a cross-sectional view illustrating a PDP filter according to an embodiment of the present invention.

Referring to FIG. 1, the PDP filter 100 includes a transparent substrate 110 and various functional layers. The functional layers include an electromagnetic shielding film 120, an adhering layer, an external-light blocking layer 140, a color compensating layer 150, and an anti-reflection layer 160. However, the present invention is not limited thereto. The filter may include a hybrid layer which can perform multiple functions. The filter may include a protection layer or other functional layers.

In FIG. 1, the electromagnetic shielding film 120, the adhering layer, the external-light blocking layer 140, and the color compensating layer 150 are arranged on one side of the transparent substrate facing a panel assembly, onto which light 180 is incident from the panel assembly. The anti-reflection layer 160 is arranged on the other side of the substrate, onto which external light 190 is incident from the outside. However, the sequence of these layers can be diversely changed.

The transparent substrate 110 can be made of an inorganic compound such as glass, quartz, or the like, or a transparent organic polymer compound. The organic polymer can be acryl or polycarbonate, but the present invention is not limited thereto. The transparent substrate 110 preferably has high transparency and heat resistance. A formed polymer substrate obtained by a forming process or a substrate in which formed polymer substrates are multi-layered can be used as the transparent substrate 110. The transparent substrate 110 preferably has a transmittance of 80% or more to visible light. As far as thermal resistance is concerned, the transparent substrate 110 preferably has a glass transition temperature of 50□ or more. The formed polymer substrate has to be transparent to visible light. Polyethylene terephthalate is preferable as the material of the transparent substrate 110, considering cost, thermal resistance and transmittance. However, the present invention is not limited thereto. The transparent substrate can also be made of heat strengthened glass. In some embodiments, the transparent substrate 110 can be excluded from the filter.

The external-light blocking layer 140 serves to preferably absorb external light so as to prevent external light from being incident to the panel assembly, and totally reflects light emitted from the panel assembly towards a viewer. Thus, the filter can have high transparency to visible ray and high contrast ratio.

The external-light blocking layer 140 includes a transparent base 142 on which a plurality of wedge grooves is formed and an external-light blocking pattern 144 which contains a light absorbent material with which the wedge grooves are filled. In some case, the external-light blocking layer may further include a backing.

The external-light blocking pattern 144 forms stripes with a wedge shape, i.e. a plurality of three-dimensional triangular prisms. However, the present invention is not limited thereto.

The external-light blocking layer 140 is arranged on the opposite side of the transparent substrate 110 from the anti-reflection layer 150. However, the present invention is not limited thereto. The layers can be layered in various sequences and directions as long as external light 190 is absorbed and light 180 is transmitted well.

In this embodiment, the bottoms of the triangular prisms of the external-light blocking pattern 144, which are formed on one side of the base 142, face the panel assembly, but the present invention is not limited to the embodiment. That is, the external-light blocking pattern 144 may be so provided that the bottoms are formed on the other side of the base to face a viewer, or the external-light blocking layers may be provided on both sides of the base.

The base 142 is a transparent, planar support which is transparent to visible ray, and may be made of glass, polyethylene terephthalate (PET), acryl, polycarbonate (PC), urethane acrylate, polyester, epoxy acrylate, brominate acrylate, polyvinyl chloride (PVC), or the like.

The external-light blocking layer 140 serves to absorb external light so as to prevent external light from being incident towards the panel assembly, and totally reflects light emitted from the panel assembly towards a viewer. Thus, the filter can have high transparency to visible ray and high contrast ratio. In addition, the external-light blocking layer 140 contains a conductive material as well as the light absorbent material in the external-light blocking pattern, thereby assisting in blocking electromagnetic waves.

While the electromagnetic shielding film 120 is arranged on one side of the transparent substrate 110 which faces the panel assembly, the present invention is not limited to the arrangement.

The electromagnetic shielding film 120 includes a transparent, resinous base 122 and an electromagnetic shielding pattern 124 with a mesh shape containing a conductive material. The electromagnetic shielding pattern 124 is so formed that intaglio grooves formed on the base are filled with the conductive material. While an electromagnetic shielding film of the related art generally has an embossed mesh pattern which bonds with a base, the electromagnetic shielding film of the present invention is provided with a metal mesh pattern which is formed by filling the intaglio mesh pattern with the conductive material.

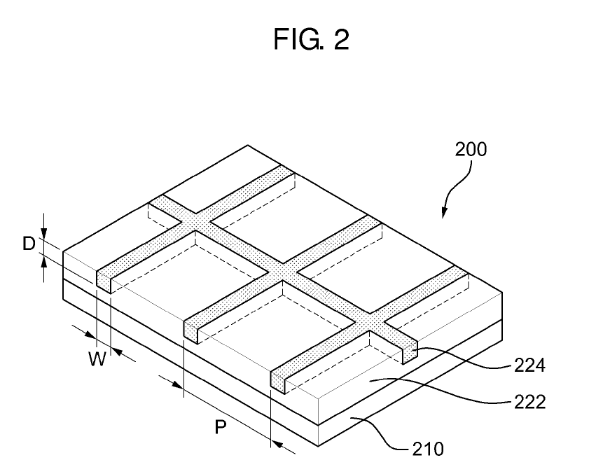

The electromagnetic shielding film of the present invention will now be described with reference to FIG. 2 together with FIG. 1.

The electromagnetic shielding film 200 includes a transparent, resinous base 222 on which an intaglio pattern is formed, and an electromagnetic shielding pattern 224. The electromagnetic shielding film further includes a backing 210.

The base is formed on the backing. An intaglio mesh pattern is formed on at least one side of the base 222. The intaglio mesh pattern is filled with a conductive material so as to form the electromagnetic shielding pattern 224.

The backing 210 may be a PET film. The conductive material may be metal paste, metal oxide powders, conductive polymer, or the combination thereof. In addition, a black material such as carbon black may be added in the mesh pattern 224 together with the conductive material, thereby assisting in absorbing light.

In order to obtain high image quality of a display, it is required to increase the aperture ratio and prevent a Moire phenomenon. To this end, it is required to restrict a width W of the mesh. If the width W is too large, the aperture ratio becomes smaller, and the amount of light is emitted from the panel assembly also decreases, which deteriorates visibility. Therefore, the width W of the mesh pattern 224 of the electromagnetic shielding film 220 is preferably 5 to 30 μm, more preferably about 15 μm.

Further, the electromagnetic blocking capability becomes excellent as a depth D of the mesh pattern 224 increases. The depth D of the mesh pattern 124 and 224 of the electromagnetic shielding film 120 and 200 is preferably 3 to 30 μm, more preferably about 10 μm. A depth E of the external-light blocking pattern 144 is about 100 μm in order to improve the light absorption efficiency.

A ratio of the depth D to the width W of the mesh pattern 224 of the electromagnetic shielding film 200 is preferably 0.3 to 3, more preferably about 0.7. In the case of the external-light shielding pattern 124, the ratio of depth to width generally exceeds 5. In the case of the electromagnetic shielding film fabricated by an existing direct print method, the mesh pattern is formed in an embossed type, the depth to width ratio has a small value of about 0.1, and it is difficult to obtain a uniform pattern. On the contrary, since the electromagnetic shielding film 200 of the present invention is formed by filling the intaglio pattern with the conductive material and the width of the intaglio pattern can be easily adjusted, the ratio of depth D to width W of the mesh pattern 224 can be easily optimized.

A distance (P in FIG. 2) between the mesh patterns ranges from 150 μm to 500 μm, which is approximately half a distance between the external-light patterns 144.

Although not illustrated, the electromagnetic shielding film 20 and the external-light blocking layer 140 may be bonded together by means of an adhering layer. The adhering layer can be used to bond the functional layers of the filter to each other. The adhering layer can include an acrylic adhesive, a silicon based adhesive, a urethane based adhesive, a polyvinyl butyral (PMB) adhesive, an ethylene-vinyl acetate (EVA) adhesive, polyvinyl ether, saturated amorphous polyester, melamine resin, or the like.

The adhering layer can be disposed between other functional layers of the filter. The adhering layer can be excluded from the filter as the case may be. The adhering layer can further contain a conductive material so as to assist the electromagnetic shielding film. The conductive material may be identical to or different from the material contained in the mesh pattern 124 of the electromagnetic shielding film 120.

Hereinafter the color compensating layer and the anti-reflection layer will be described with reference again to FIG. 1.

In an embodiment, the PDP filter 100 includes the color compensating layer 150 to selectively absorb light in a specific range of a wavelength. The color compensating layer 150 reduces or adjusts the amounts of red light, green light, or blue light so as to change or correct a color balance, thereby increasing the color reproduction range of display and degree of definition.

The color compensating layer 150 contains various kinds of colorants, namely dyes or pigments. The colorants can include an organic pigment having a function of blocking neon light such as anthraquinone dye, cyanine dye, azo dye, styryl dye, phthalocyanine dye, methyl dye, or the like. Since the sort and concentration of the colorants are determined considering an absorption wavelength and absorption coefficient of the colorant, and a characteristic of transmittance required for a display, they are not limited to specific ones.

Although not illustrated in the figures, the PDP filter 100 may include a near-infrared ray blocking layer. The near-infrared ray blocking layer blocks strong near-infrared rays, which are caused by the panel assembly and causes the malfunction of electronic appliances such as a cellular phone or a remote controller. In order to block near-infrared rays, the near-infrared ray blocking layer can include a polymer resin containing an absorption pigment which can absorb near-infrared rays. For example, the absorption pigment may be an organic pigment such as a cyanine type pigment, an anthraquinone type pigment, a naphtoquinone type pigment, a phthalocyanine type pigment, a naphthalocyanine type pigment, a diimmonium type pigment, a nickel dithiol type pigment, or the like.

The anti-reflection layer 160 prevents external light, which is incident from a direction of a viewer, from being reflected again towards the outside, so as to improve a contrast ratio. While in the present embodiment, the anti-reflection layer 160 is formed on the other side of the transparent substrate 110, the present invention is not limited to this embodiment. However, preferably, it is efficient that, when the PDP filter 100 is installed on the PDP, the anti-reflection layer 160 is formed on the side of the filter facing a viewer, as illustrated in FIG. 1. Particularly, a thin film which is made of fluoric transparent polymer resin, magnesium fluoride, silicon resin or silicon oxide with a refractive index of 1.5 or less, preferably 1.4 or less in a visible range and is single-layered in the thickness of e.g. ¼ wavelength can be used as the anti-reflection layer 160. In addition, the anti-reflection layer 160 can be made by multi-layering two or more thin films of an inorganic compound such as metal oxide, fluoride, silicide, boride, carbide, nitride, sulfide, etc., or an organic compound such as silicon resin, acryl resin, fluoric resin, etc whose refractive indices are different from each other.

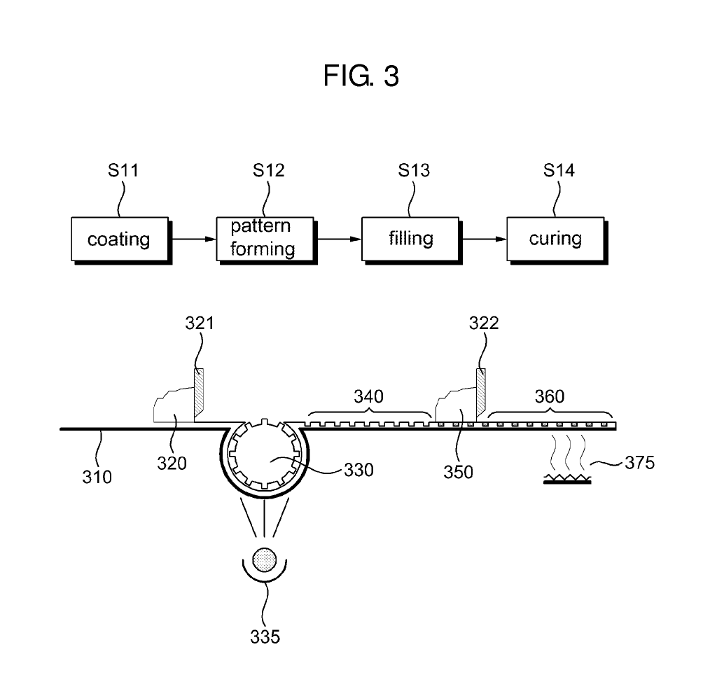

A method of fabricating the electromagnetic shielding film of the present invention will now be described in detail with reference to FIG. 3.

Referring to FIG. 3, the fabricating method includes a coating step S11, a pattern-forming step S12, a filling step S13, and a curing step S14.

In the coating step S11, a first curable resin 320 is applied onto one surface of a transparent backing 310. The transparent backing 310 may be a PET film. The first curable resin 320 may be UV-curable resin. In this step, the UV-curable resin in a pre-cured state is applied onto the transparent backing 310, and then is flattened to have a desired thickness using a blade 321.

Next, in the pattern-forming step S12, an intaglio mesh pattern is formed on the UV-curable resin using a cylinder type patterning roll 330 having an embossed mesh pattern, and then the UV-curable resin is exposed to UV emitted from an UV lamp 335 so as to cure the UV-curable resin, thereby forming a base 340 having the intaglio pattern. Alternatively, if the tension of the transparent backing 310 and the viscosity of the first curable resin are properly regulated, the coating step S11 may be skipped.

According to the shape of the embossed pattern of the patterning roll 330, the shape of the electromagnetic shielding pattern can be made different. Since the patterning roll 330 having an embossed pattern with a small width and high ratio of depth to width can be easily made by etching or machining, the optimal electromagnetic shielding pattern can be easily obtained as well.

Not only UV-curable resin but also heat-curable resin can be used as the first curable resin.

Next, in the filling step S13, a second curable resin 350 containing a conductive material is applied and the intaglio pattern is filled with the second curable resin by a wiping method using a blade 322. The conductive material may be silver paste which is UV-curable or heat-curable. In addition, in order to reduce reflectivity more, the second curable resin 350 may further include a black material such as carbon black. When heat-curable resin is employed as the second curable resin 350, the curing step S14 may be carried out using an infrared heater 375. After the curing step S14 completes, an electromagnetic shielding film 360 in which the intaglio pattern is filled with the conductive material is obtained.

Via the above-mentioned steps, three kinds of electromagnetic shielding films having different widths, different depths, and different distances (pitches), were prepared, and they are shown in Table 1 below as examples 1 through 3. Comparative example 1 shows a result of a test for a mesh film of LG Micron, Co., Ltd. which is fabricated by a conventional etching method.

TABLE 1

| | | | | Comparative |
|---|---|---|---|---|
| | Example 1 | Example 1 | Example 3 | Example 1 |
| Distance P, μm | 300 | 300 | 300 | 300 |
| Depth, D, μm | 10.4 | 7.8 | 5.2 | 10 |
| Width, W, μm | 10 | 10 | 7 | 10 |
| Sheet | 0.29 | 0.39 | 0.84 | 0.04 |
| Resistance, Ω/□ | | | | |
| Transmittance, % | 47.5 | 47.5 | 48.4 | 47.9 |

From the results of Table 1, it can be seen that the examples 1 to 3 of the electromagnetic shielding films of the present invention all have such a low sheet resistance as to block electromagnetic waves very well, and such a high transmittance as to be used as a part of a filter for a display device. As compared to the conventional electromagnetic shielding film made by the etching method, the electromagnetic shielding film of the present invention has a superior or similar performance, and it fabricating process becomes efficient and cost-effective, so it is expected to be widely used in the future.

Preferred embodiments of the present invention have been described for illustrative purposes. Those skilled in the art will appreciate that various modifications, additions and substitutions are possible, without departing from the scope and spirit of the invention as disclosed in the accompanying claims.

What is claimed is:

1. An electromagnetic shielding film for a display device comprising:
a transparent, resinous first base, an intaglio pattern formed on at least one side of the first base; and
an electromagnetic shielding pattern which contains a conductive material with which the intaglio pattern is filled.

2. The electromagnetic shielding film according to claim 1, wherein the intaglio pattern is a mesh pattern.

3. The electromagnetic shielding film according to claim 1, wherein the intaglio pattern has a depth of 3 to 30 μm and a width of 5 to 30 μm, and a ratio of the depth to the width is ranged between 0.3 and 3.

4. The electromagnetic shielding film according to claim 1, wherein the conductive material is any one of (i) metal paste containing at least one metal of Co, Al, Zn, Zr, Pt, Au, Pd, Ti, Fe, Sn, In, Ni, Mo, W, Ag, and Cu, (ii) powders of at least one metal oxide of copper oxide, zinc oxide, indium oxide, tin oxide, indium tin oxide, aluminum zinc oxide, and indium zinc oxide, and (iii) at least one conductive polymer of polythiophene, polypyrrole, polyaniline, poly(3,4-ethylenedioxythiophene), poly(3-alkylthiophene), polyisothianaphthene, poly(p-phenylenevinylene), poly(p-phenylene), and derivatives thereof.

5. The electromagnetic shielding film according to claim 1, comprising a backing on which the first base is formed.

6. A filter for a display device comprising an electromagnetic shielding film including:
a transparent, resinous first base, an intaglio pattern formed on at least one side of the first base; and
an electromagnetic shielding pattern which contains a conductive material with which the intaglio pattern is filled.

7. The filter for a display device according to claim 6, comprising an external-light blocking layer,
wherein the external-light blocking layer comprises a transparent second base on which a plurality of wedge grooves is formed and an external-light blocking pattern which contains a light absorbent material with which the wedge grooves are filled.

8. A method of fabricating an electromagnetic shielding film for a display device, the method comprising the steps of:
coating a first curable resin on one surface of a transparent backing;
forming an intaglio pattern on the first curable resin using a patterning roll and curing the first curable resin;
filling the intaglio pattern with a second curable resin containing a conductive material; and
curing the second curable resin.

9. The method according to claim 8, wherein the intaglio pattern is a mesh pattern.

10. The method according to claim 8, wherein the first curable resin is an ultraviolet-curable resin, and the second curable resin is a heat-curable resin.

11. The method according to claim 8, wherein in the filling step, the intaglio pattern is filled with the second curable resin containing the conductive material using a wiping method.
